(19) United States
(12) Patent Application Publication
(10) Pub. No.: US 2024/0320528 A1
(43) Pub. Date: Sep. 26, 2024

(54) METROLOGY TARGET OPTIMIZATION

(71) Applicant: ASML NETHERLANDS B.V., Veldhoven (NL)

(72) Inventors: Patrick Philipp HELFENSTEIN, Eindhoven (NL); Scott Anderson MIDDLEBROOKS, Duizel (NL); Markus Gerardus Martinus Maria VAN KRAAIJ, Eindhoven (NL); Maxim PISARENCO, Son en Breugel (NL)

(73) Assignee: ASML NETHERLANDS B.V., Veldhoven (NL)

(21) Appl. No.: 18/579,560

(22) PCT Filed: Aug. 17, 2022
(86) PCT No.: PCT/EP2022/072980

§ 371 Date: Jan. 16, 2024

(30) Foreign Application Priority Data
Aug. 18, 2021 (EP) 21191852.9

(51) Int. Cl. G06N 7/01

(52) U.S. Cl. CPC G06N 7/01

(57) ABSTRACT

A method of designing a target includes obtaining a model of an initial dataset, performing a Bayesian optimization using the model which provides an improved model, and performing an optimization of the target design using the improved model.

### TECHNICAL FIELD

The present invention relates to metrology target simulation. In particular, the present invention relates to a computer implemented method of simulating an electromagnetic response of a metrology target having a multi-layer structure.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k1.

Semiconductor-based devices may be produced by fabricating a series of layers on a substrate (e.g., a wafer), some or all of the layers including various structures. The relative position of these structures within a single layer and with respect to structures in other layers plays a key role in the performance of the devices. Overlay error relates to the misalignment between various structures. Overlay accuracy generally pertains to the determination of how accurately a first patterned layer aligns with respect to a second patterned layer disposed above or below it and to the determination of how accurately a first pattern aligns with respect to a second pattern disposed on the same layer. Overlay measurements are performed via metrology targets that are printed together with layers of the wafer. Images of the metrology targets are captured via an imaging tool and are analyzed to determine both X-overlay and Y-overlay measurements.

Known techniques exist to simulate an electromagnetic response of a metrology target in software before fabricating them onto a substrate. This simulation enables a designer to determine one or more parameters associated with the electromagnetic response of the metrology target and make changes to the design of the metrology target to optimize the one or more parameters.

### SUMMARY

Known techniques for simulating an electromagnetic response of a metrology target are typically applied to metrology targets comprising a multi-layer structure comprising an upper grating and a lower grating, wherein the grating lines of the upper grating and the lower grating have the same pitch. This involves rigorously simulating the electromagnetic response of the metrology target using Maxwell solvers, e.g. using Rigorous Coupled-Wave Analysis (RCWA), for various parameters of light incident on the metrology target and for different critical dimensions (CD) and pitches of the metrology target.

The inventors had identified that when the grating lines of the upper grating and the lower grating are not equal, i.e. have different pitches, the computational complexity of the simulation increases such that using known Maxwell solving techniques take a much greater length of time making the use of known Maxwell solving techniques for such a metrology target design impractical or sometimes even impossible.

According to one aspect of the present disclosure there is provided method of designing a target comprising providing an initial dataset, obtaining a model of the initial dataset, performing a Bayesian optimization using the model which provides an improved model, performing an optimization of the target design using the improved model.

According to one aspect of the present disclosure there is provided a computer implemented method of designing a metrology target for a semiconductor wafer, the metrology target having a multi-layer structure comprising a first grating and a second grating, wherein the second grating is below the first grating in the multi-layer structure, the method comprising: for each of a plurality of candidate metrology targets, performing the method of any preceding claim and determining one or more parameters associated with the electromagnetic response of the candidate metrology target using the scattering matrix of the candidate metrology target; identifying a candidate metrology target from said plurality of candidate metrology targets that optimizes said one or more parameters.

According to another aspect of the present disclosure there is provided a computing device comprising a processor and memory, the memory storing instructions which, when executed by the processor cause the computing device to perform the method steps described herein.

According to another aspect of the present disclosure there is provided a computer-readable storage medium comprising instructions which, when executed by a processor of a computing device cause the computing device to perform the method steps described herein.

The instructions may be provided on a carrier such as a disk, CD- or DVD-ROM, programmed memory such as read-only memory (Firmware), or on a data carrier such as an optical or electrical signal carrier. Code (and/or data) to implement embodiments of the present disclosure may comprise source, object or executable code in a conventional programming language (interpreted or compiled) such as C, or assembly code, code for setting up or controlling an ASIC (Application Specific Integrated Circuit) or FPGA (Field Programmable Gate Array), or code for a hardware description language.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 schematically depicts an example computing device on which embodiments can be implemented;

FIG. 5a schematically depicts a portion of a metrology target the electromagnetic response of which may be simulated in embodiments of the present disclosure;

FIGS. 5b and 5c illustrates a top view of an upper grating and a lower grating of an example metrology target the electromagnetic response of which may be simulated in embodiments of the present disclosure;

FIGS. 5d and 5e illustrates a top view of an upper grating and a lower grating of another example metrology target the electromagnetic response of which may be simulated in embodiments of the present disclosure;

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

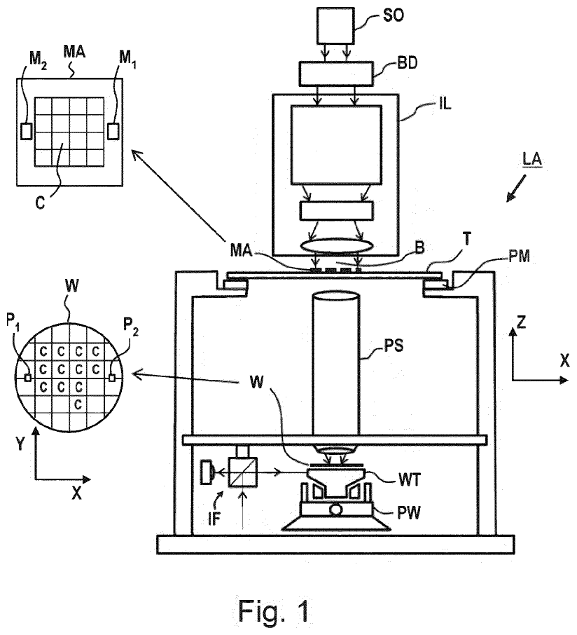

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

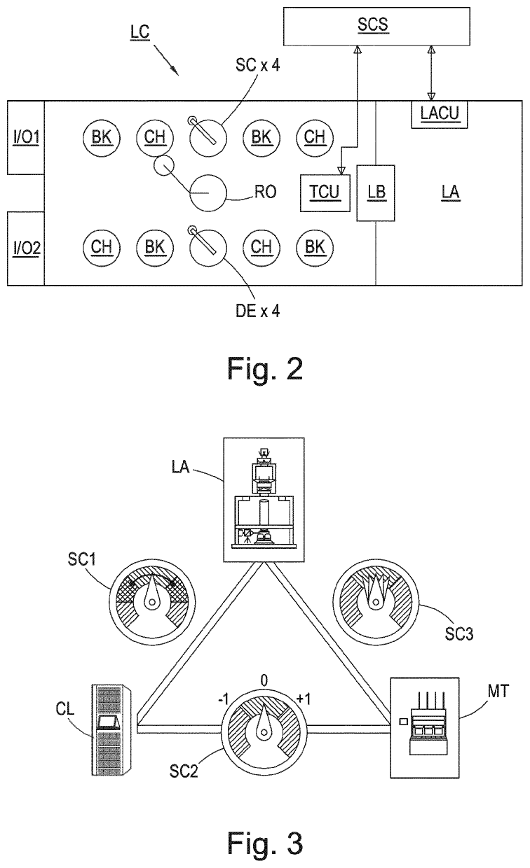

As shown in FIG. 2 the lithographic apparatus LA may form part of a lithographic cell LC, also sometimes referred to as a lithocell or (litho)cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

Typically the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MT (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MT) to predict whether defects may be present due to e.g. sub-optimal processing (depicted in FIG. 3 by the arrow pointing “0” in the second scale SC2).

The metrology tool MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

A metrology target on the substrate W is used to determine the alignment of different layers of the same substrate W. Embodiments of the present disclosure relate to the software simulation of an electromagnetic response of a candidate metrology target as part of a design process for determining an optimal metrology target that is to be manufactured on a substrate W. The simulation method described herein is performed on a computing device 400. The computing device 400 may be the same as, or a separate device to, the computer system CL.

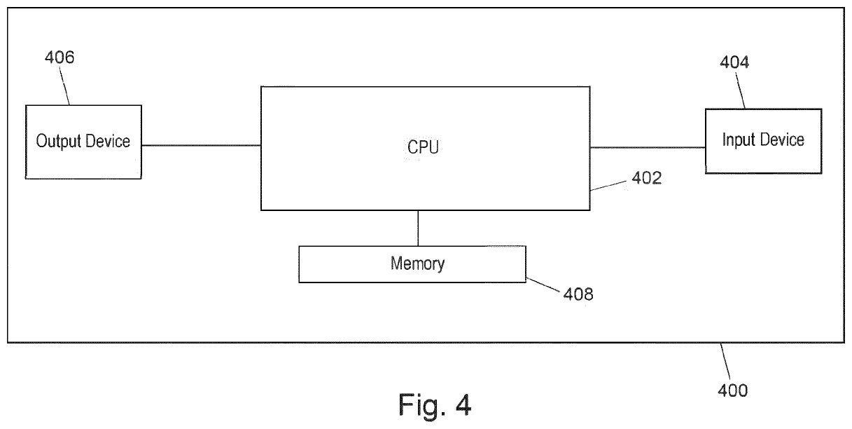

FIG. 4 illustrates a simplified view of the computing device 400. A shown in FIG. 4, the device 402 comprises a central processing unit (“CPU”) 202, to which is connected a memory 408. The functionality of the CPU 402 described herein may be implemented in code (software) stored on a memory (e.g. memory 408) comprising one or more storage media, and arranged for execution on a processor comprising on or more processing units. The storage media may be integrated into and/or separate from the CPU 402. The code is configured so as when fetched from the memory and executed on the processor to perform operations in line with embodiments discussed herein. Alternatively it is not excluded that some or all of the functionality of the CPU 402 is implemented in dedicated hardware circuitry, or configurable hardware circuitry like an FPGA.

The computing device 400 comprises an input device 404 configured to enable a user to input data into a software program running on the CPU 402 for the simulation of an electromagnetic response of a candidate metrology target. The input device 404 may comprise a mouse, keyboard, touchscreen, microphone etc. The computing device 400 further comprises an output device 406 configured to output results of the simulation to the user. The output device 406 may for example be a display (which may comprise a touchscreen) or a speaker.

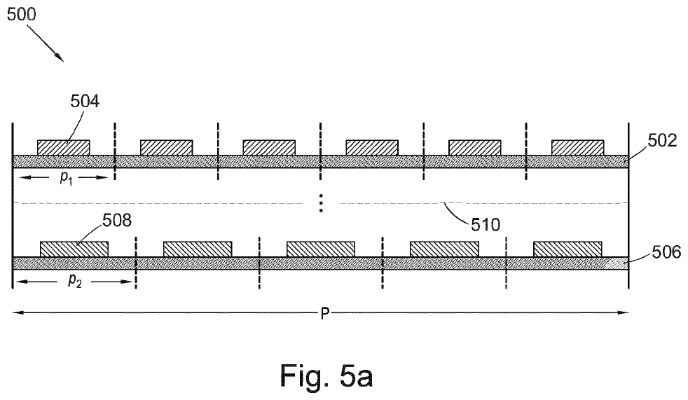

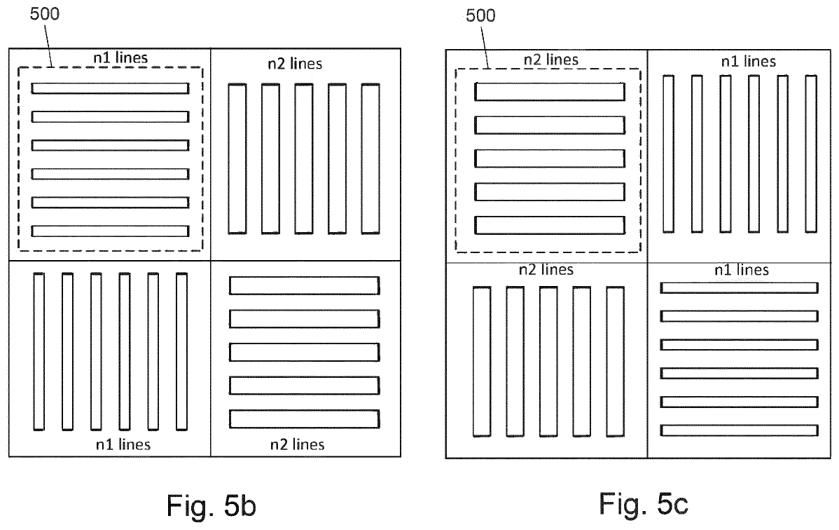

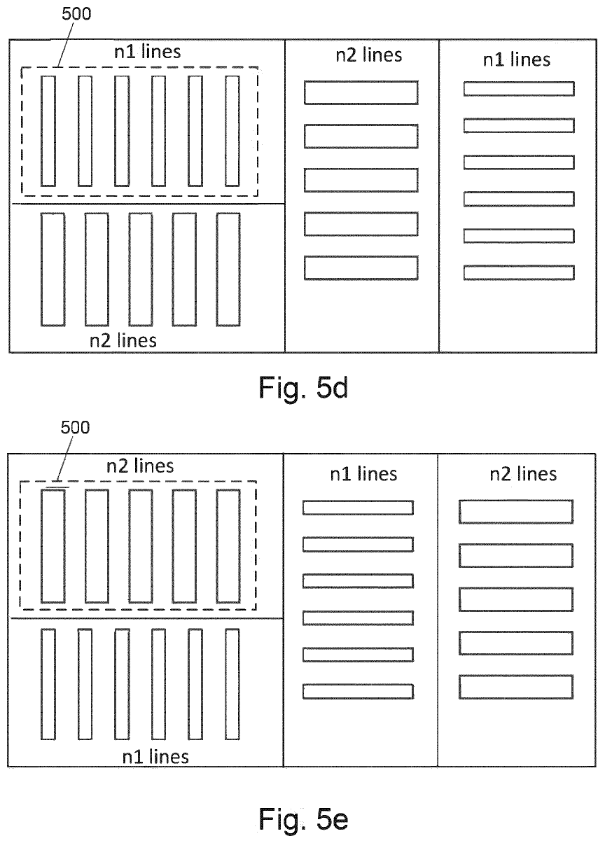

FIG. 5a schematically depicts a portion 500 of a metrology target the electromagnetic response of which may be simulated by the software program running on the CPU 402 in embodiments of the present disclosure.

As shown in FIG. 5a, the portion 500 of the metrology target comprises a top grating (also referred to herein as a first grating) 504 on a first substrate 502 and a bottom grating (also referred to herein as a second grating) on a second substrate 506, wherein the bottom grating is below the top grating. Whilst embodiments of the present disclosure are described with reference to the simulation of a metrology target comprising two gratings for simplicity, it will be appreciated that embodiments of the present disclosure extend to metrology targets having more than two layers of gratings. FIG. 5a shows a gap between the first substrate 502 and second substrate 506. It will be appreciated that the first substrate may extend down to the second substrate 506. Alternatively this gap may comprise one or more additional layers of material.

The top grating has a first predetermined number (n1) of grating lines 504 within a pitch P of the portion 500 of the metrology target. FIG. 5a shows the top grating having 6 grating lines as a mere example (i.e. n1=6). All of the grating lines 504 on the top grating are identical (e.g. in dimensions and material).

The bottom grating has a second predetermined number (n2) of grating lines 506 within the pitch P of the portion 500 of the metrology target. FIG. 5a shows the bottom grating having 5 grating lines as a mere example (i.e. n2=5). All of the grating lines 506 on the bottom grating are identical (e.g. in dimensions and material).

The portion 500 represents a cell defining the boundaries of a periodic structure, and is thus referred to herein as a unit cell of size Pnm. Each of the first predetermined number of grating lines within the pitch P of the unit cell are separated by a first sub-pitch p1, and each of the second predetermined number of grating lines within the pitch P of the unit cell are separated by a second sub-pitch p2. In the unit cell 500 shown in FIG. 5a, the sub-pitch p₁ is different from the sub-pitch p₂ resulting in a large pitch P of the unit cell where P=6p₁=5p₂. Whilst FIG. 5a shows a portion 500 of the metrology target where the first predetermined number n1 of grating lines 504 is greater than the second predetermined number n2 of grating lines 508 such that the first sub-pitch p1 is less than the second sub-pitch p2, as shown in FIGS. 5b-5d in another portion of the metrology target the first predetermined number n1 of grating lines 504 is less than the second predetermined number n2 of grating lines 508 such that the first sub-pitch p1 is greater than the second sub-pitch p2. As mere examples, p1 may equal 500 nm and p2 may equal 600 nm resulting in the pitch P of the unit cell being 3000 nm.

FIG. 5b illustrates a top view of a top grating of an example metrology target incorporating the portion 500, and FIG. 5c illustrates a top view of a bottom grating of the example metrology target shown in FIG. 5b. As shown in FIGS. 5b and 5c, the metrology target comprises four sections. In the top left section (comprising portion 500), on the top grating the periodicity of the n1 lines runs along the vertical direction (with the lines themselves being orientated horizontally) and on the bottom grating the periodicity of the n2 lines runs along the vertical direction. In the top right section, on the top grating the periodicity of the n2 lines runs along the horizontal direction and on the bottom grating the periodicity of the n1 lines runs along the horizontal direction. In the bottom left section, on the top grating the periodicity of the n1 lines runs along the horizontal direction and on the bottom grating the periodicity of the n2 lines runs along the horizontal direction. In the bottom right section, on the top grating the periodicity of the n2 lines runs along the vertical direction and on the bottom grating the periodicity of the n1 lines runs along the vertical direction. The overlay error between two layers on a substrate is measured using an image of the metrology target, i.e., that is in an active area of a substrate. By illuminating the metrology target from two opposing directions (each direction by itself being a cone of light and thus containing many different angles of incidence). The two images coming from the two (opposing) illuminations are then analyzed to extract overlay. This analysis may comprise computing a phase difference between top and bottom gratings (which manifest as an intensity fringe pattern that translates as a function of overlay).

In a variant of the metrology target shown in FIGS. 5b and 5c, an alternative metrology target may have the horizontal and vertical swapped around such that for the top left section (corresponding to portion 500), on the top grating n1 lines would run horizontally and on the bottom grating n2 lines would run horizontally, and so on.

FIG. 5d illustrates a top view of a top grating of another example metrology target incorporating the portion 500, and FIG. 5e illustrates a top view of a bottom grating of the example metrology target shown in FIG. 5d.

In the metrology target shown in FIGS. 5b-e, for simplicity each quadrant is shown as corresponding to the large pitch P of the unit cell. However it will be appreciated that in some implementations there may be multiple (e.g. 2 or 3 or more) repeats of the large pitch P in a quadrant of the metrology target. The computation described herein for a quadrant of a metrology target can still be performed based on a single large pitch P.

In all of these examples, the large pitch P of the unit cell directly impacts the runtime of Maxwell solver simulations which scales cubically in unit cell size, i.e. a computational hit of (3000/600)\hat{ }3=125 can be observed. This computational hit makes rigorous simulation of a metrology target design such as that shown in FIG. 5a to be impractical or sometimes even impossible.

Furthermore, when one is designing a target as depicted in FIG. 5a, one is confronted with a large number of parameters to be optimized, which creates a lot of time needed to perform all the possible optimization options. To arrive at a robust target design, candidates are chosen via a brute-force approach that considers all possible target candidates. Since there is no optimization, all parameter combinations have to be calculated, resulting in a high computational cost of goods.

Thus, instead of exhaustively calculating all possible parameter combinations, it is proposed a method of designing a target comprising providing an initial dataset, obtaining a model of the initial dataset, performing a Bayesian optimization using the model which provides an improved model, performing an optimization of the target design using the improved model.

In a first step an initial dataset is provided.

In a second step, a model is trained based on the initial dataset.

In a third step, a Bayes optimization is performed to propose new experimental conditions via Expected Improvement.

In a fourth step, proposals are obtained as output to step three.

In a fifth step, it is evaluated an expensive model or experiment.

In a sixth step, it is checked whether the model has the desired accuracy by comparing the accuracy of the improved model with a predefined threshold accuracy. The predefined threshold accuracy may be provided by a user.

If no, additional dataset is accumulated and provided to the initial dataset of step one, such that the training of the model at step 2 may be improved.

If yes, a final model is trained

In a seventh step, Bayes optimization is performed to design an optimal target using the final trained model.

In an eight step, proposal are obtained as a result of the Bayes optimization.

In a nineth step, the optimal target design is obtain based on the proposal of step eight.

In a further embodiment of the invention, a system is provided comprising one or more processors and memory storing instructions that when executed by at least some of the processors effectuate operations comprising: obtaining a model of the initial dataset provide, performing a Bayesian optimization using the model which provides an improved model and performing an optimization of the target design using the improved model.

Embodiments of the present disclosure extend to a computer implemented method of designing a metrology target for a semiconductor wafer, the metrology target having a multi-layer structure comprising a first grating and a second grating, wherein the second grating is below the first grating in the multi-layer structure, the method comprising: for each of a plurality of candidate metrology targets, performing the method described herein and determining one or more parameters associated with the electromagnetic response of the candidate metrology target using the scattering matrix of the candidate metrology target; and identifying a candidate metrology target from said plurality of candidate metrology targets that optimizes said one or more parameters. This method of designing a metrology target for a semiconductor wafer may comprises performing the method described herein for a predetermined number of candidate metrology targets after which the identifying is performed. Alternatively, this method of designing a metrology target for a semiconductor wafer may comprise repeating the method described herein for different candidate metrology targets until a candidate metrology target is found which satisfies predetermined criteria relating to the one or more parameters.

Whilst the methods described herein have been described with reference to a first (upper) grating and the second (lower) grating being unequal (i.e. different pitches), the methods described herein can also be used to simulate the performance of structures where the number of grating lines of the upper grating and the lower grating are equal, i.e. have the same pitch).

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A method of designing a metrology target, the method comprising:
obtaining a model of an initial dataset,
performing a Bayesian optimization using the model which provides an improved model, and
performing, by one or more hardware processors, an optimization of the metrology target design using the improved model.

2. The method according to claim 1, wherein the Bayesian optimization is performed to propose new experimental conditions via Expected Improvement.

3. The method according to claim 2, wherein proposals are obtained as output of the Bayesian optimization.

4. The method according to claim 3, wherein an improved model is evaluated as an expensive model or experiment.

5. The method according to claim 4, wherein an accuracy of the improved model is verified by comparing it to a predefined threshold accuracy.

6. The method according to claim 5, wherein the predefined threshold accuracy is provided by a user.

7. The method according to claim 4, wherein an additional dataset is accumulated and provided to the initial dataset such that the improved model is improved.

8. The method according to claim 1, wherein the optimization of the target design using the improved model is a Bayes optimization.

9. A system comprising:
one or more processors; and
memory storing instructions that, when executed by the one or more processors, are configured to cause the one or more processors to at least:
obtain a model of an initial dataset,
perform a Bayesian optimization using the model which provides an improved model, and
perform an optimization of a metrology target design using the improved model.

10. The system according to claim 9, wherein the Bayesian optimization is performed to propose new experimental conditions via Expected Improvement.

11. The system according to claim 9, wherein an improved model is evaluated as an expensive model or experiment.

12. The system according to claim 9, wherein the optimization of the target design using the improved model is a Bayes optimization.

13. A non-transitory storage medium comprising instructions therein, the instructions, when executed by one or more processors, are configured to cause the one or more processors to at least:
obtain a model of an initial dataset,
perform a Bayesian optimization using the model which provides an improved model, and
perform an optimization of a metrology target design using the improved model.

14. The medium according to claim 13, wherein the Bayesian optimization is performed to propose new experimental conditions via Expected Improvement.

15. The medium according to claim 14, wherein proposals are obtained as output of the Bayesian optimization.

16. The medium according to claim 13, wherein an improved model is evaluated as an expensive model or experiment.

17. The medium according to claim 13, wherein an accuracy of the improved model is verified by comparing it to a predefined threshold accuracy.

18. The medium according to claim 17, wherein the predefined threshold accuracy is provided by a user.

19. The medium according to claim 13, wherein an additional dataset is accumulated and provided to the initial dataset such that the improved model is improved.

20. The medium according to claim 13, wherein the optimization of the target design using the improved model is a Bayes optimization.
